(19) United States
(12) Patent Application Publication
(10) Pub. No.: US 2019/0004982 A1
(43) Pub. Date: Jan. 3, 2019

(54) BUFFER CIRCUIT AND DEVICE INCLUDING THE SAME

(71) Applicant: SK hynix Inc., Gyeonggi-do (KR)

(72) Inventor: Jae-Heung KIM, Gyeonggi-do (KR)

(21) Appl. No.: 15/847,503

(22) Filed: Dec. 19, 2017

Related U.S. Application Data
(60) Provisional application No. 62/526,670, filed on Jun. 29, 2017.

(51) Int. Cl. G06F 13/16; G06F 13/40

(52) U.S. Cl. CPC G06F 13/1673; G11C 11/34; G06F 13/4022

(57) ABSTRACT

A circuit may include: a first buffer suitable for operating at a first supply voltage, buffering input data received through an input terminal, and outputting the buffered data to an output terminal; and a second buffer suitable for operating at a second supply voltage, buffering the input data received through the input terminal, and outputting the buffered data to the output terminal. The first and second buffers may share the output terminal, and alternately perform output operations under control of a control signal.

### CROSS-REFERENCE TO RELATED APPLICATIONS

The present application claims priority to U.S. Provisional Patent Application No. 62/526,670 entitled, “OUTPUT MERGED RX BUFFER”, filed on Jun. 29, 2017, which is Incorporated herein by reference in its entirety.

### BACKGROUND

### 1. Field

Exemplary embodiments of the present invention relate to a buffer circuit.

### 2. Description of the Related Art

Electronic devices such as computers, mobile phones, and storage devices may include integrated circuits (ICs) having various elements or circuits integrated therein. Each of the ICs may be coupled to one or more external circuits or devices, and include buffers as components for interfacing the external circuits or devices. Since the external circuits or devices may use various voltages, each of the ICs may have a variety of interface elements corresponding to the types of voltages used therein.

### SUMMARY

Various embodiments are directed to a circuit having buffers capable of supporting various voltages.

In an embodiment, a circuit may include: a first buffer suitable for operating at a first supply voltage, buffering input data received through an input terminal, and outputting the buffered data to an output terminal; and a second buffer suitable for operating at a second supply voltage, buffering the input data received through the input terminal, and outputting the buffered data to the output terminal. The first and second buffers may share the output terminal, and alternately perform output operations under control of a control signal.

In an embodiment, a memory device may include: a memory cell array; and a circuit suitable for providing data received from a data pad to the memory cell array. The circuit may include: a first buffer suitable for operating at a first supply voltage, buffering input data received through an input terminal, and outputting the buffered data to an output terminal; and a second buffer suitable for operating at a second supply voltage, buffering the input data received through the input terminal, and outputting the buffered data to the output terminal. The first and second buffers may share the output terminal, and alternately perform output operations under control of a control signal.

### BRIEF DESCRIPTION OF THE DRAWINGS

FIGS. 1A and 1B are diagrams Illustrating a data processing system.

FIG. 2 is a diagram illustrating a memory device in accordance with an embodiment.

FIG. 3 is a diagram Illustrating a conventional circuit including a plurality of buffers for supporting various supply voltages.

FIG. 4 is a diagram Illustrating a circuit including a plurality of buffers capable of supporting various supply voltages in accordance with an embodiment of the present disclosure.

FIG. 5 is a diagram illustrating output operations of the plurality of buffers in accordance with the present embodiment.

FIG. 6 is a diagram illustrating block configurations of the buffers in accordance with the present embodiment.

FIG. 7 is a diagram illustrating on/off operations of components included in the buffers in accordance with the present embodiment.

FIG. 8 is a diagram illustrating circuit configurations of the buffers in accordance with the present embodiment.

FIG. 9 is a diagram illustrating on/off operations of components included in the buffers in accordance with the present embodiment.

### DETAILED DESCRIPTION

Exemplary embodiments will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and, in some instances, proportions may have been exaggerated in order to clearly Illustrate features of the embodiments.

It will be further understood that when an element is referred to as being “connected to”, or “coupled to” another element, it may be directly on, connected to, or coupled to the other element, or one or more intervening elements may be present. In addition, it will also be understood that when an element is referred to as being “between” two elements, it may be the only element between the two elements, or one or more intervening elements may also be present.

The terminology used herein is for the purpose of describing particular embodiments only and is not intended to be limiting of the present invention.

It will be further understood that the terms “comprises,” “comprising,” “includes,” and “including” when used in this specification, specify the presence of the stated elements and do not preclude the presence or addition of one or more other elements. As used herein, the term “and/or” includes any and all combinations of one or more of the associated listed items.

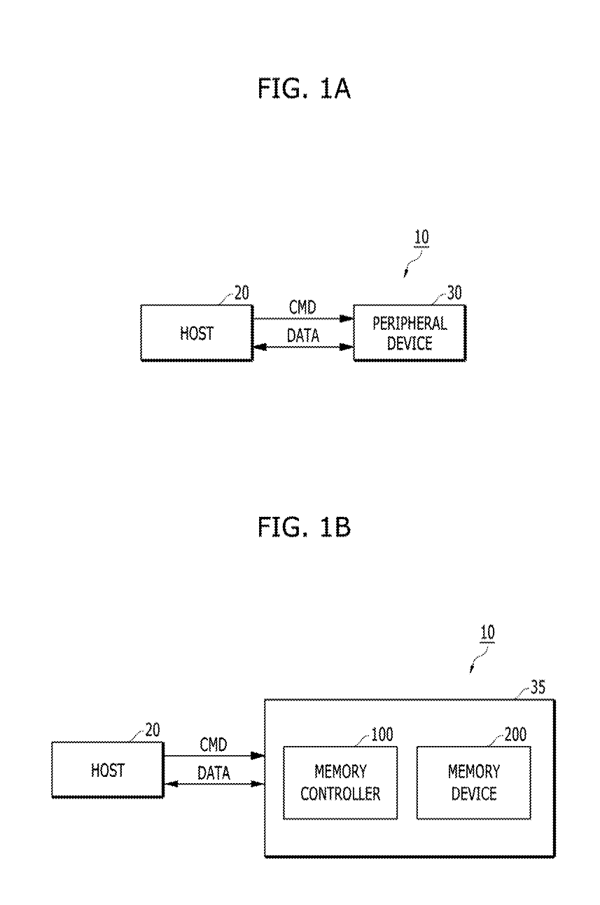

Hereinafter, the various embodiments of the present invention will be described in detail with reference to the attached drawings. FIGS. 1A and 1B are diagrams illustrating a data processing system 10.

Referring to FIG. 1A, the data processing system 10 may include a host 20 and a peripheral device 30. The peripheral device may receive a command CMD (or request) from the host 20, and exchange data DATA with the host 20 according to the received command CMD. For example, the host 20 may correspond to a computer, server, smart phone or the like, and the peripheral device may correspond to a mobile or storage product.

Referring to FIG. 1B, the peripheral device 30 illustrated in FIG. 1A may be implemented by a memory system 35. That is, the data processing system 10 may include the host 20 and the memory system 35. The host 20 may include portable electronic devices such as a mobile phone, MP3 player and laptop computer or electronic devices such as a desktop computer, game machine, TV and projector.

The memory system 35 may be accessed in response to a command from the host 20. In other words, the memory system 35 may be used as a main storage device or secondary storage device of the host 20.

The memory system 35 may include a memory controller 100 and a memory device 200. The memory controller 100 may access to the corresponding memory device 200 in response to a command from the host 20. For example, the memory controller 100 may store write data from the host 20 in the memory device 200 in response to a write command from the host 20. For another example, the memory controller 100 may read data stored in the memory device 200 in response to a read command from the host 20, and transfer the read data to the host 20. In various embodiments, the memory device 200 may include volatile memory devices such as dynamic random access memory (DRAM) and static RAM (SRAM). In other embodiments, the memory device 200 may include nonvolatile memory devices such as read only memory (ROM), mask ROM (MROM), programmable ROM (PROM), erasable ROM (EPROM), electrically erasable ROM (EEPROM), ferromagnetic RAM (FRAM), phase change RAM (PRAM), magnetic RAM (MRAM), resistive RAM (RRAM), and flash memory.

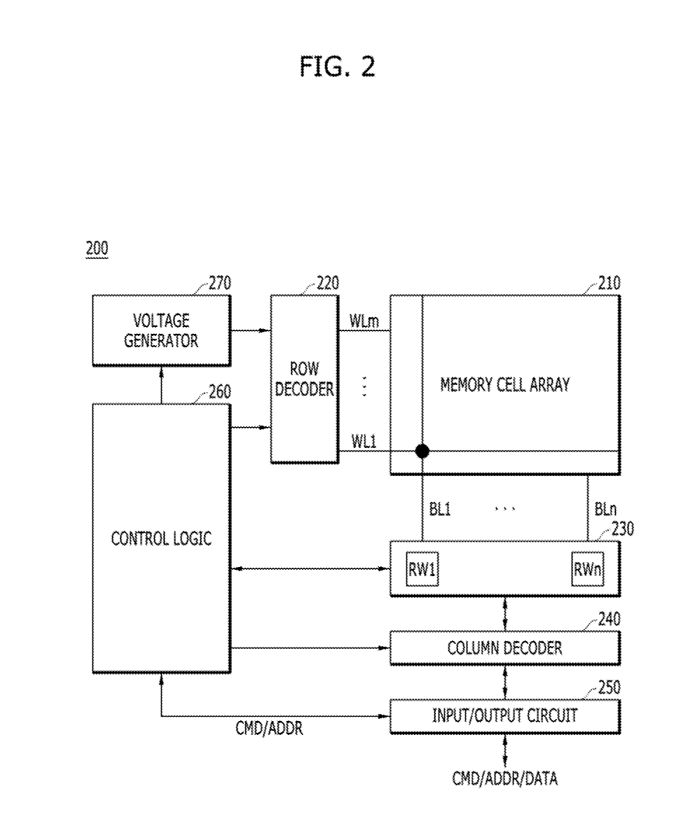

FIG. 2 is a diagram illustrating a memory device 200 in accordance with an embodiment. For example, FIG. 2 illustrates the configuration of a nonvolatile memory device which can be used as the memory device 200 of FIG. 1B.

Referring to FIG. 2, the memory device 200 may include a memory cell array 210, a row decoder 220, a data read/write block 230, a column decoder 240, an input/output circuit 250, a control logic 260 and a voltage generator 270.

The memory cell array 210 may include memory cells MC arranged at the respective intersections between word lines WL1 to WLm and bit lines BL1 to BLn.

The row decoder 220 may be coupled to the memory cell array 210 through the word lines WL1 to WLm. The row decoder 220 may be operated under control of the control logic 260. The row decoder 220 may decode an address provided from an external device (for example, the memory controller 100 of FIG. 1B). The row decoder 220 may select and drive the word lines WL1 to WLm based on the decoding result. For example, the row decoder 220 may provide a word line voltage provided from the voltage generator 270 to the word lines WL1 to WLm.

The data read/write block 230 may be coupled to the memory cell array 210 through the bit line BL1 to BLn. The data read/write block 230 may include read/write circuits RW1 to RWn corresponding to the respective lines BL1 to BLn. The data read/write block 230 may be operated under control of the control logic 260. The data read/write block 230 may operate as a write driver or sense amplifier, depending on its operation mode. For example, the data read/write block 230 may operate as a write driver that stores data provided from the external device to the memory cell array 210 during a write operation. For another example, the data read/write block 230 may operate as a sense amplifier that reads data from the memory cell array 210 during a read operation.

The column decoder 240 may be operated under control of the control logic 260. The column decoder 240 may decode an address provided from the external device. The column decoder 240 may couple the read/write circuits RW1 to RWn of the data read/write block 230, corresponding to the respective bit lines BL1 to BLn, to a data input/output line of the input/output circuit 250 based on the decoding result.

The voltage generator 270 may generate voltages used for internal operations of the memory device 200. The voltages generated by the voltage generator 270 may be applied to memory cells of the memory cell array 210. For example, a program voltage generated during a program operation may be applied to a word line of memory cells on which the program operation is to be performed. For another example, an erase voltage generated during an erase operation may be applied to a well region of memory cells on which the erase operation is to be performed. For another example, a read voltage generated during a read operation may be applied to a word line of memory cells on which the read operation is to be performed.

The control logic 260 may control overall operations of the memory device 200 based on a signal provided from the external device through the input/output circuit 250. For example, the control logic 260 may control the read, write, and erase operations of the memory device 200.

The input/output circuit 250 may transfer a command CMD and address ADDR received from the external device to the control logic 260, or exchange data DATA with the column decoder 240. Furthermore, the input/output circuit 250 may be coupled to the column decoder 240, and output read data sensed by the data read/write block 230 to the external device through input/output lines (not Illustrated). Moreover, the input/output circuit 250 may transfer data received through the input/output lines to the data read/write block 230 through the column decoder 240.

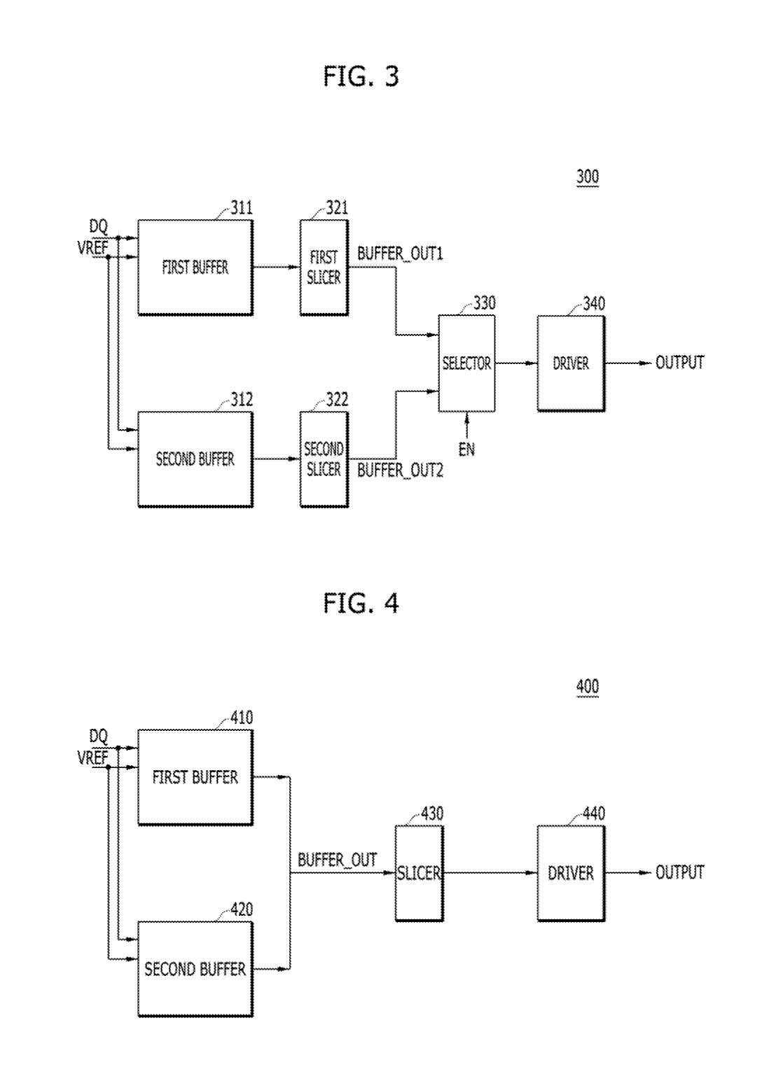

FIG. 3 is a diagram Illustrating a conventional circuit 300 including a plurality of buffers for supporting various supply voltages.

Referring to FIG. 3, the circuit 300 may include buffers, slicers, a selector, and a driver as elements for interfacing an external device. When the circuit 300 is designed to support various supply voltages which can be used in one or more external devices, the circuit 300 may include interface elements corresponding to the types or number of supply voltages. For example, the circuit 300 may include interface elements capable of supporting two kinds of supply voltages. That is, the circuit 300 may include a first buffer 311 and a first slicer 321 as interface elements which are operated at a first supply voltage, and include a second buffer 312 and a second slicer 322 as interface elements which are operated at a second supply voltage.

The first buffer 311 may buffer input data received through an input terminal, and output the buffered data. For example, the first buffer 311 may receive input data through a data pad DQ, and amplify a differential signal corresponding to a difference between the received input data and a reference voltage VREF.

The first slicer 321 may slice the buffered data outputted from the first buffer 311, and output the sliced signal. For example, the first slicer 321 may slice the buffered data to a level (for example, CMOS level) which can be processed in a device including the circuit 300, and output a signal BUFFER_OUT1. The device may include the memory device 200 of FIG. 1B, for example.

The second buffer 312 may buffer input data received through the input terminal, and output the buffered data. For example, the second buffer 312 may receive input data through the data pad DQ, and amplify a differential signal corresponding to a difference between the received input data and the reference voltage VREF.

The second slicer 322 may slice the buffered data outputted from the second buffer 312, and output the sliced signal. For example, the second slicer 322 may slice the buffered data to a level (for example, CMOS level) which can be processed in the device including the circuit 300, and output a signal BUFFER_OUT2. The device may include the memory device 200 of FIG. 1B, for example.

A selector 330 may select an output of any one slicer between the first and second slicers 321 and 322, in response to an enable signal EN. For example, the selector 330 may select the signal BUFFER_OUT1 outputted from the first slicer 321 in response to the enable signal EN corresponding to the first supply voltage, or select the signal BUFFER_OUT2 outputted from the second slicer 322 in response to the enable signal EN corresponding to the second supply voltage.

The driver 340 may receive the signal BUFFER_OUT1 or BUFFER_OUT2 from the first or second slicer 321 or 322, the signal BUFFER_OUT1 or BUFFER_OUT2 being selected by the selector 330, and output the received signal BUFFER_OUT1 or BUFFER_OUT2 as an output signal OUTPUT to an output terminal, thereby driving the output terminal.

FIG. 4 is a diagram illustrating a circuit 400 including a plurality of buffers capable of supporting various supply voltages in accordance with an embodiment of the present disclosure. For example, the circuit 400 may be included in the input/output circuit 250 of the memory device 200 illustrated in FIG. 2.

Referring to FIG. 4, the circuit 400 may include buffers, a slicer and a driver for interfacing an external device. When the circuit 400 is designed to support various supply voltages which can be used in one or more external devices, the circuit 400 may include buffers corresponding to the types or number of supply voltages. For example, the circuit 400 may include a buffer 410 capable of operating at a first supply voltage (e.g., 1.2V), and a buffer 420 capable of operating at a second supply voltage (e.g., 1.8V). Unlike the circuit 300, the circuit 400 may include a single slicer 430, and a driver 440 without any selector.

The first buffer 410 may be operated at the first supply voltage, buffer input data received through an input terminal, and output the buffered data. For example, when the first buffer 410 includes a differential amplifier, the first buffer 410 may receive input data through a data pad DQ, and amplify a differential signal corresponding to a difference between the received input data and a reference voltage VREF.

The second buffer 420 may be operated at the second supply voltage, buffer input data received through the input terminal, and output the buffered data. For example, when the second buffer 420 includes a differential amplifier, the second buffer 420 may receive input data through the data pad DQ, and amplify a differential signal corresponding to a difference between the received input data and the reference voltage VREF.

The first and second buffers 410 and 420 may alternately output the buffered data. In various embodiments, during an output operation of any one buffer between the first and second buffers 410 and 420, the other buffer may float from the output terminal. Thus, the first and second buffers 410 and 420 may alternately perform output operations.

The slicer 430 may slice the buffered data outputted from any one buffer of the first and second buffers 410 and 420, and output the sliced signal. For example, the slicer 430 may slice the buffered data to a level (for example, CMOS level) which can be processed in a device including the circuit 400, and output a signal BUFFER_OUT. The device may include the memory device 200 of FIG. 1B, for example.

The driver 440 may receive the signal BUFFER_OUT from the slicer 430, and output the received signal BUFFER_OUT as an output signal OUTPUT to an output terminal, thereby driving the output terminal.

The circuit 400 illustrated in FIG. 4 may be used to implement a combination buffer circuit capable of supporting a plurality of supply voltages. The output nodes of the buffers 410 and 420 can be commonly merged, and the buffers 410 and 420 can share the single slicer 430. Therefore, the circuit 400 can not only reduce the number of slicers, but also remove the selector, compared to the circuit 300 illustrated in FIG. 3. In the embodiment of FIG. 4, the circuit 400 may include the buffers 410 and 420, the slicer 430, and the driver 440. However, the present embodiments may be applied the circuit without a slicer, only including buffers and a driver.

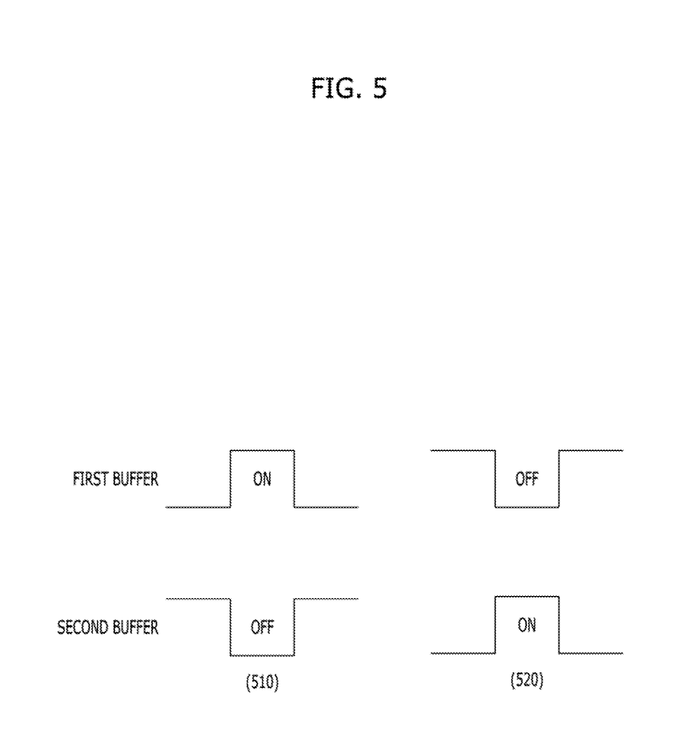

FIG. 5 is a diagram illustrating output operations of a plurality of buffers in accordance with an embodiment. For example, FIG. 5 illustrates output operations of the buffers 410 and 420 included in the circuit 400 of FIG. 4.

Referring to reference numeral 510, an output operation of the second buffer 420 is blocked (“OFF”) during an output operation (“ON”) of the first buffer 410. Similarly, referring to reference numeral 520, during an output operation (“ON”) of the second buffer 420, an output operation of the first buffer 410 is blocked (“OFF”).

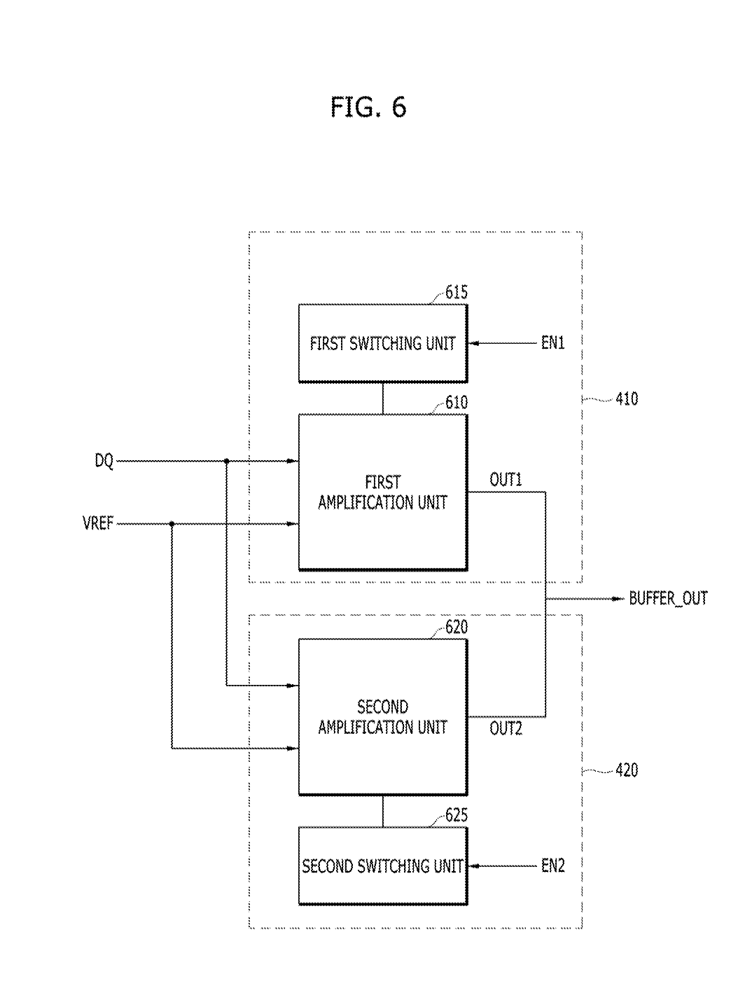

FIG. 6 is a diagram illustrating the block configurations of buffers in accordance with an embodiment. For example, FIG. 6 illustrates the block configurations of the buffers 410 and 420 included in the circuit 400 of FIG. 4.

Referring to FIG. 6, the first buffer 410 may be operated at the first supply voltage of 1.2V, for example, buffer input data received through the input terminal, and output the buffered data. For example, the first buffer 410 may receive the input data through the data pad DQ, and amplify a differential signal corresponding to a difference between the received input data and the reference voltage VREF.

The first buffer 410 may include a first amplification unit 610 and a first switching unit 615. The first amplification unit 610 may receive the reference voltage VREF and the input data received through the data pad DQ, amplify a differential signal corresponding to a difference between the received input data and the reference voltage VREF, and output first output data OUT1. The first switching unit 615 may be switched in response to a first enable signal EN1. When the first switching unit 615 is switched on, the first amplification unit 610 may perform an output operation. On the other hand, when the first switching unit 615 is switched off, the output operation of the first amplification unit 610 may be blocked.

The second buffer 420 may be operated at the second supply voltage of 1.8V, for example, buffer input data received through the Input terminal, and output the buffered data. For example, the second buffer 420 may receive the input data through the data pad DQ, and amplify a differential signal corresponding to a difference between the received input data and the reference voltage VREF.

The second buffer 420 may include a second amplification unit 620 and a second switching unit 625. The second amplification unit 620 may receive the reference voltage VREF and the input data received through the data pad DQ, amplify a differential signal corresponding to a difference between the received input data and the reference voltage VREF, and output second output data OUT2. The second switching unit 625 may be switched in response to a second enable signal EN2. When the second switching unit 625 is switched on, the second amplification unit 620 may perform an output operation. On the other hand, when the second switching unit 625 is switched off, the output operation of the switching unit 625 may be blocked.

The output nodes of the first and second buffers 410 and 420 may be coupled to each other, and the output data OUT1 and OUT2 may be outputted through the coupled output nodes. The first buffer 410 may output the buffered data in response to the first enable signal EN1. The second buffer 420 may output the buffered data in response to the second enable signal EN2. In various embodiments, the first and second enable signals EN1 and EN2 may be alternately enabled.

Therefore, the first and second buffers 410 and 420 may alternately output the buffered data in response to the first and second enable signals EN1 and EN2, respectively. In other words, when any one buffer of the first and second buffers 410 and 420 is enabled to perform an output operation, the other buffer may be disabled not to perform an output operation.

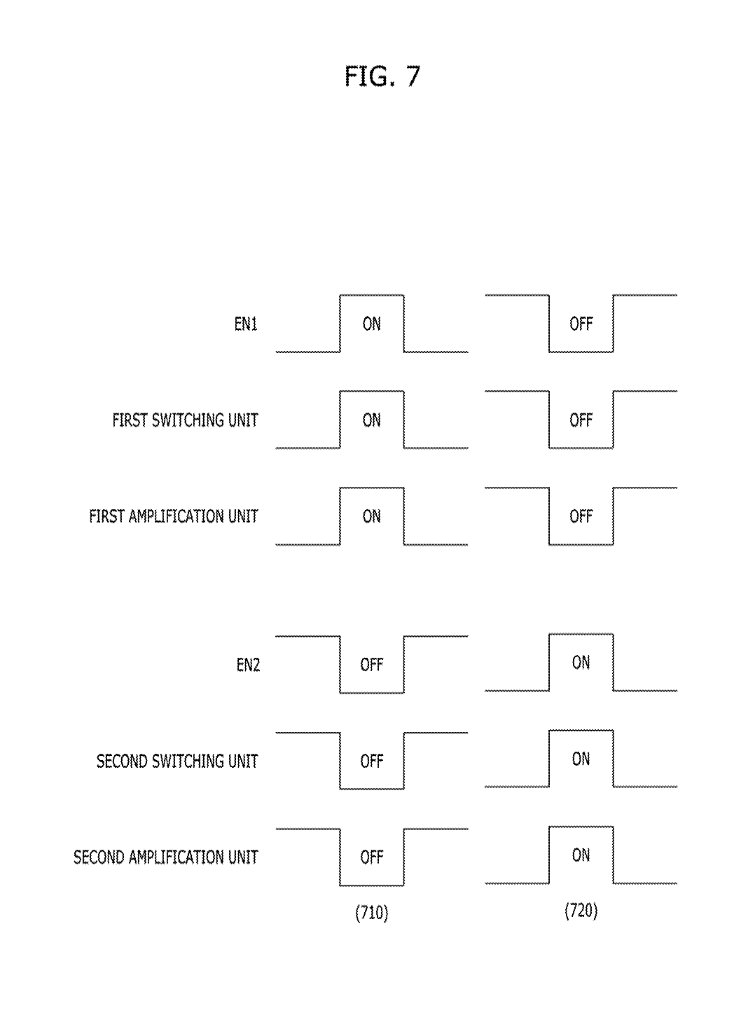

FIG. 7 is a diagram Illustrating on/off operations of the components included in the buffers in accordance with the present embodiment. For example, FIG. 7 illustrates the operations of the first amplification unit 610 and the first switching unit 615 that are included in the first buffer 410 of FIG. 6, and the operations of the second amplification unit 620 and the second switching unit 625 that are included in the second buffer 420.

Referring to reference numeral 710 of FIG. 7, when the first enable signal EN1 Is in the “ON” state, the first switching unit 615 included in the first buffer 410 may be switched on. Thus, the first amplification unit 610 may output buffered data by performing a buffering operation.

When the first enable signal EN1 is in the “ON” state, the second enable signal EN2 may have the “OFF” state. When the second enable signal EN2 is in the “OFF” state, the second switching unit 625 included in the second buffer 420 may be switched off. Thus, a data output operation of the second amplification unit 620 may be blocked.

Referring to reference numeral 720, when the first enable signal EN1 is in the “OFF” state, the first switching unit 615 included in the first buffer 410 may be switched off. Thus, a data output operation of the first amplification unit 610 may be blocked.

When the first enable signal EN1 is in the “OFF” state, the second enable signal EN2 may have the “ON” state. When the second enable signal EN2 is in the “ON” state, the second switching unit 625 included in the second buffer 420 may be switched on. Thus, the second amplification unit 620 may output buffered data by performing a buffering operation.

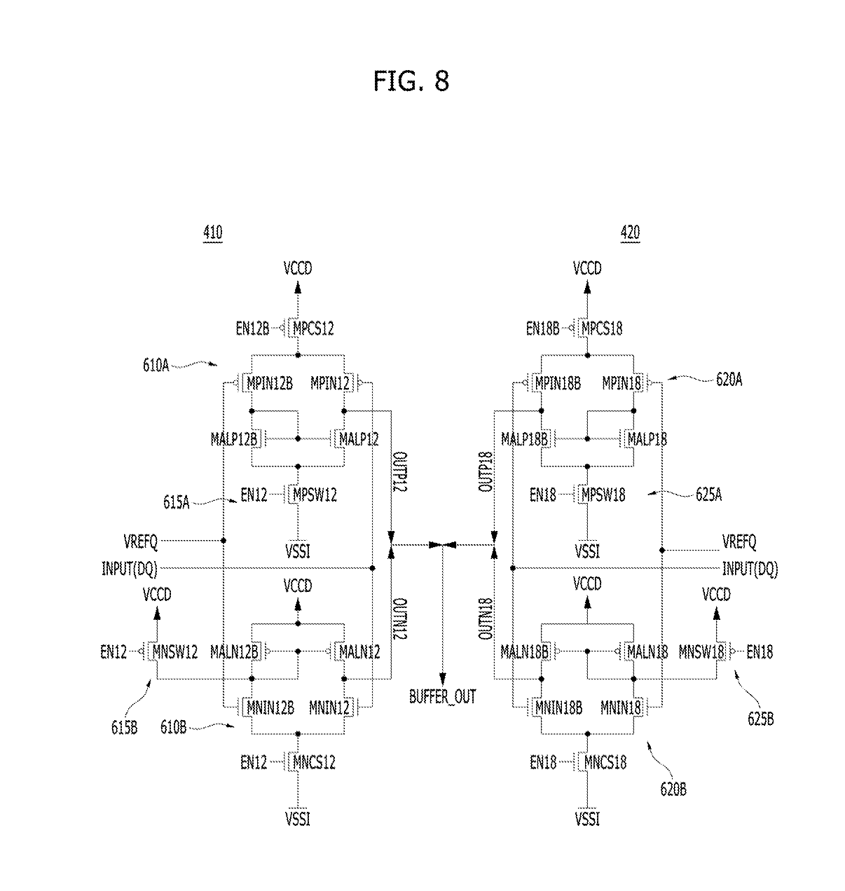

FIG. 8 is a diagram illustrating the circuit configurations of the buffers in accordance with the present embodiment. For example, FIG. 8 illustrates components constituting the first and second buffers 410 and 420 of FIG. 6.

Referring to FIG. 8, the first buffer 410 may include an amplification unit 610A, a switching unit 615A, an amplification unit 610B and a switching unit 615B.

The amplification unit 610A and the switching unit 615A may be coupled in series between a supply voltage terminal VCCD and a ground terminal VSSI.

The amplification unit 610A may include an amplifier and a PMOS transistor MPCS12. The amplifier may include a PMOS transistor pair MPIN12B and MPIN12 and an NMOS transistor pair MALP12B and MALP12. The PMOS transistor MPCS12 may include a first terminal coupled to the supply voltage terminal VCCD, a second terminal coupled to receive an enable signal EN12B, and a third terminal. The PMOS transistor MPCS12 may perform a switching operation in response to the enable signal EN12B. The PMOS transistor PMCS12 may be switched on to provide a current to the amplifier.

The PMOS transistor MPIN12B of the amplifier may include a first terminal coupled to the third terminal of the transistor MPCS12, a second terminal coupled to receive a reference voltage VREFQ, and a third terminal coupled to a first terminal of the transistor MALP12B. The PMOS transistor MPIN12 may include a first terminal coupled to the third terminal of the transistor MPCS12, a second terminal coupled to the data pad DQ, and a third terminal coupled to a first terminal of the transistor MALP12. The third terminal of the transistor MPIN12 may be coupled to the output node of the first buffer 410. The PMOS transistor pair MPIN12B and MPIN12 may constitute a differential pair.

The NMOS transistor MALP12B of the amplifier may include the first terminal coupled to the third terminal of the transistor MPIN12B, a second terminal coupled to a second terminal of the transistor MALP12, and a third terminal coupled to a first terminal of a transistor MPSW12. The first and second terminals of the transistor MALP12B may be coupled to each other. The NMOS transistor MALP12 may include the first terminal coupled to the third terminal of the transistor MPIN12, the second terminal coupled to the second terminal of the transistor MALP12B, and a third terminal coupled to the first terminal of the transistor MPSW12. The first terminal of the transistor MALP12 may be coupled to the output node of the first buffer 410. The NMOS transistors MALP12B and MALP12 may constitute a current mirror.

The amplifier of the amplification unit 610A may receive the reference voltage VREFQ and input data INPUT received through the data pad DQ, amplify a differential signal corresponding to a difference between the input data and the reference voltage, and output data OUTP12 as the amplification result to the output node.

The switching unit 615A implemented by an NMOS transistor MPSW12 may perform a switching operation in response to the enable signal EN12. The NMOS transistor MPSW12 may include the first terminal coupled to the third terminals of the NMOS transistors MALP12B and MALP12, a second terminal coupled to receive the enable signal EN12, and a third terminal coupled to the ground terminal VSSI. When the switching unit 615A is switched on, the amplification unit 610A may output the data OUTP12 corresponding to the amplification result. On the other hand, when the switching unit 615A is switched off, an output of the data OUTP12 corresponding to the amplification result by the amplification unit 610A may be blocked.

The amplification unit 610B and the switching unit 615B may be coupled in parallel between the supply voltage terminal VCCD and the ground terminal VSSI.

The amplification unit 610B may include an amplifier and an NMOS transistor MNCS12. The amplifier may include a PMOS transistor pair MALN12B and MALN12 and an NMOS transistor pair MNIN12B and MNIN12.

The PMOS transistor MALN12B of the amplifier may include a first terminal coupled to the supply voltage terminal VCCD, a second terminal coupled to a second terminal of the transistor MNIN12, and a third terminal coupled to a first terminal of the transistor MNIN12B. The second and third terminals of the transistor MALN12B may be coupled to each other. The PMOS transistor MALN12 may include a first terminal coupled to the supply voltage terminal VCCD, a second terminal coupled to the second terminal of the transistor MALN12B, and a third terminal coupled to a first terminal of the transistor MNIN12. The third terminal of the transistor MALN12 may be coupled to the output node of the first buffer 410. The PMOS transistors MALN12B and MALN12 may constitute a current mirror.

The NMOS transistor MNIN12B of the amplifier may include the first terminal coupled to the third terminal of the transistor MALN12B, a second terminal coupled to receive the reference voltage VREFQ, and a third terminal coupled to a first terminal of the transistor MNCS12. The NMOS transistor MNIN12 may include a first terminal coupled to the third terminal of the transistor MALN12, a second terminal coupled to the data pad DQ, and a third terminal coupled to the first terminal of the transistor MNCS12. The NMOS transistor pair MNIN12B and MNIN12 may constitute a differential pair.

The amplifier of the amplification unit 610B may receive the reference voltage VREFQ and input data INPUT received through the data pad DQ, amplify a differential signal corresponding to a difference between the input data and the reference voltage, and output data OUTN12 as the amplification result to the output node.

The NMOS transistor MNCS12 may include the first terminal coupled to the third terminals of the NMOS transistor pair MNIN12B and MNIN12, a second terminal coupled to receive the enable signal EN12, and a third terminal coupled to the ground terminal VSSI. The transistor MNCS12 may perform a switching operation in response to the enable signal EN12. The transistor MNCS12 may be switched on to sink a tail current from the amplifier.

The switching unit 615B implemented by a PMOS transistor MNSW12 may perform a switching operation in response to the enable signal EN12. The PMOS transistor MNSW12 may include a first terminal coupled to the supply voltage terminal VCCD, a second terminal coupled to receive the enable signal EN12, and a third terminal coupled to the third terminal of the transistor MALN12B, the first terminal of the transistor MNIN12B, and the second terminals of the transistor pair MALN12B and MALN12. When the switching unit 615B is switched on, the amplification unit 610B may output the data OUTN12 corresponding to the amplification result. On the other hand, when the switching unit 615B is switched off, an output of the data OUTN12 corresponding to the amplification result by the amplification unit 610B may be blocked.

Referring to FIG. 8, the second buffer 420 may include an amplification unit 620A, a switching unit 625A, an amplification unit 6208 and a switching unit 625B.

The amplification unit 620A and the switching unit 625A may be coupled in series between the supply voltage terminal VCCD and the ground terminal VSSI.

The amplification unit 620A may include an amplifier and a PMOS transistor MPCS18. The amplifier may include a PMOS transistor pair MPIN18B and MPIN18 and an NMOS transistor pair MALP18B and MALP18. The PMOS transistor MPCS18 may include a first terminal coupled to the supply voltage terminal VCCD, a second terminal coupled to receive an enable signal EN18B, and a third terminal. The PMOS transistor MPCS18 may perform a switching operation in response to the enable signal EN12B. The PMOS transistor MPCS18 may be switched on to provide a current to the amplifier.

The PMOS transistor MPIN18B of the amplifier may include a first terminal coupled to the third terminal of the transistor MPCS18, a second terminal coupled to the data pad DQ, and a third terminal coupled to a first terminal of the transistor MALP18B. The third terminal of the transistor MPIN18B may be coupled to an output node of the second buffer 420. The PMOS transistor MPIN18 may include a first terminal coupled to the third terminal of the transistor MPCS18, a second terminal coupled to receive the reference voltage VREFQ, and a third terminal coupled to a first terminal of the transistor MALP18. The PMOS transistor pair MPIN18B and MPIN18 may constitute a differential pair.

The NMOS transistor MALP18B of the amplifier may include the first terminal coupled to the third terminal of the transistor MPIN18B, a second terminal coupled to a second terminal of the transistor MALP18, and a third terminal coupled to a first terminal of a transistor MPSW18. The first terminal of the transistor MALP18B may be coupled to the output node of the second buffer 420. The NMOS transistor MALP18 may include the first terminal coupled to the third terminal of the transistor MPIN18, the second terminal coupled to the second terminal of the transistor MALP18B, and a third terminal coupled to the first terminal of the transistor MPSW18. The first and second terminals of the transistor MALP18B may be coupled to each other. The NMOS transistors MALP18B and MALP18 may constitute a current mirror.

The amplifier of the amplification unit 620A may receive the reference voltage VREFQ and input data INPUT received through the data pad DQ, amplify a differential signal corresponding to a difference between the input data and the reference voltage, and output data OUTP18 as the amplification result to the output node.

The switching unit 625A implemented by the NMOS transistor MPSW18 may perform a switching operation in response to the enable signal EN18. The NMOS transistor MPSW18 may include the first terminal coupled to the third terminals of the NMOS transistors MALP18B and MALP18, a second terminal coupled to receive the enable signal EN18, and a third terminal coupled to the ground terminal VSSI. When the switching unit 625A is switched on, the amplification unit 620A may output the data OUTP18 corresponding to the amplification result. On the other hand, when the switching unit 625A is switched off, an output of the data OUTP18 corresponding to the amplification result by the amplification unit 620A may be blocked.

The amplification unit 620B and the switching unit 625B may be coupled in parallel between the supply voltage terminal VCCD and the ground terminal VSSI.

The amplification unit 620B may include an amplifier and an NMOS transistor MNCS18. The amplifier may include a PMOS transistor pair MALN18B and MALN18 and an NMOS transistor pair MNIN18B and MNIN18.

The PMOS transistor MALN18B of the amplifier may include a first terminal coupled to the supply voltage terminal VCCD, a second terminal coupled to a second terminal of the transistor MALN18, and a third terminal coupled to a first terminal of the transistor MNIN18B. The third terminal of the transistor MALN18B may be coupled to the output node of the first buffer 420. The PMOS transistor MALN18 may include a first terminal coupled to the supply voltage terminal VCCD, the second terminal coupled to the second terminal of the transistor MALN18B, and a third terminal coupled to the first terminal of the transistor MNIN18. The second and third terminals of the transistor MALN18B may be coupled to each other. The PMOS transistors MALN18B and MALN18 may constitute a current mirror.

The NMOS transistor MNIN18B of the amplifier may include the first terminal coupled to the third terminal of the transistor MALN18B, a second terminal coupled to the data pad DQ, and a third terminal coupled to a first terminal of the transistor MNCS18. The NMOS transistor MNIN18 may include a first terminal coupled to the third terminal of the transistor MALN18, a second terminal coupled to receive the reference voltage VREFQ, and a third terminal coupled to the first terminal of the transistor MNCS18. The NMOS transistor pair MNIN18B and MNIN18 may constitute a differential pair.

The amplifier of the amplification unit 620B may receive the reference voltage VREFQ and input data INPUT received through the data pad DQ, amplify a differential signal corresponding to a difference between the input data and the reference voltage, and output data OUTN18 as the amplification result to the output node.

The NMOS transistor MNCS18 may include the first terminal coupled to the third terminals of the NMOS transistor pair MNIN18B and MNIN18, a second terminal coupled to receive the enable signal EN18, and a third terminal coupled to the ground terminal VSSI. The transistor MNCS18 may perform a switching operation in response to the enable signal EN18. The transistor MNCS18 may be switched on to sink a tail current from the amplifier.

The switching unit 625B implemented by a PMOS transistor MNSW18 may perform a switching operation in response to the enable signal EN18. The PMOS transistor MNSW18 may include a first terminal coupled to the supply voltage terminal VCCD, a second terminal coupled to receive the enable signal EN18, and a third terminal coupled to the third terminal of the transistor MALN18, the first terminal of the transistor MNIN18, and the second terminals of the transistor pair MALN18B and MALN18. When the switching unit 625B is switched on, the amplification unit 620B may output the data OUTN18 corresponding to the amplification result. On the other hand, when the switching unit 625B is switched off, an output of the data OUTN18 corresponding to the amplification result by the amplification unit 620B may be blocked.

In the embodiment of FIG. 8, it has been described that each of the first and second buffers 410 and 420 includes two amplification units and two switching units. However, each of the first and second buffers 410 and 420 may include one amplification unit and one switching unit. For example, the first buffer 410 may include the amplification unit 610A and the switching unit 615A, and the second buffer 420 may include the amplification unit 620A and the switching unit 625A. For another example, the first buffer 410 may include the amplification unit 610B and the switching unit 615B, and the second buffer 420 may include the amplification unit 620B and the switching unit 625B.

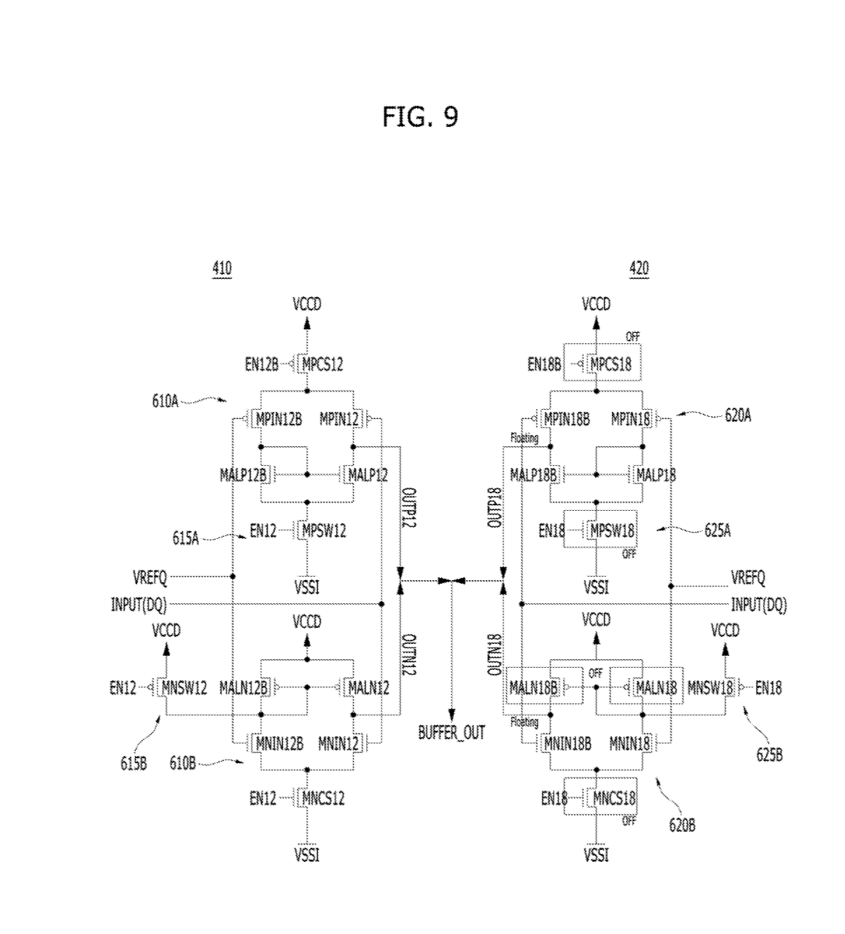

FIG. 9 is a diagram illustrating on/off operations of components included in the buffers in accordance with the present embodiment. FIG. 9 illustrates on/off operations of the components included in the first and second buffers 410 and 420 of FIG. 8.

Referring to FIG. 9, when an output operation is performed by the first buffer 410, the transistor MPCS18 included in the amplification unit 620A of the second buffer 420 and the transistor MPSW18 constituting the switching unit 625A may be switched off. For example, when the enable signal EN1 provided to the first buffer 410 has the ON state (for example, logic “H” level), the first buffer 410 may perform an output operation. On the other hand, when the enable signal EN2 provided to the second buffer 420 has the OFF state (for example, logic “L” level), the transistors MPCS18 and the transistor MPSW18 of the second buffer 420 may be switched off. As the transistor MPCS18 and the transistor MPSW18 of the second buffer 420 are switched off, the output node of the second buffer 420 may have a floating state.

Furthermore, when an output operation is performed by the first buffer 410, the transistors MALN18B, MALN18 and MNCS18 included in the amplification unit 620B of the second buffer 420 may be switched off. For example, when the enable signal EN1 provided to the first buffer 410 has the ON state (for example, logic “H” level), the first buffer 410 may perform an output operation. On the other hand, when the enable signal EN2 provided to the second buffer 420 has the OFF state (for example, logic “L” level), the transistors MALN18B, MALN18 and MNCS18 of the second buffer 420 may be switched off. As the transistors MALN18B, MALN18 and MNCS18 of the second buffer 420 are switched off, the output node of the second buffer 420 may have a floating state.

As such, when the first buffer 410 performs an output operation and an output operation of the second buffer 420 is blocked by the floating state of the output node, only an output signal by the first buffer 410 may be outputted as the buffer output signal BUFFER_OUT to the output terminal coupled to the output nodes of the first and second buffers 410 and 420.

Similarly, when the second buffer 420 performs an output operation and an output operation of the first buffer 410 is blocked by the floating state of the output node, only an output signal by the second buffer 420 may be outputted as the buffer output signal BUFFER_OUT to the output terminal coupled to the output nodes of the first and second buffers 410 and 420.

In accordance with the embodiments, when a combination buffer circuit including a plurality of buffers capable of supporting a plurality of supply voltages is implemented, output nodes of the respective buffers can be commonly merged, and the buffers can be controlled to alternately perform output operations. Therefore, the number of components corresponding to the respective buffers can be reduced, and a component for selecting only one output among outputs of the buffers can be removed.

Although various embodiments have been described for illustrative purposes, it will be apparent to those skilled in the art that various changes and modifications may be made without departing from the spirit and scope of the invention as defined in the following claims.

What is claimed is:

1. A circuit comprising:
a first buffer suitable for operating at a first supply voltage, buffering input data received through an input terminal, and outputting the buffered data to an output terminal; and
a second buffer suitable for operating at a second supply voltage, buffering the input data received through the input terminal, and outputting the buffered data to the output terminal,
wherein the first and second buffers share the output terminal, and alternately perform output operations under control of a control signal.

2. The circuit of claim 1, further comprising:
a slicer suitable for slicing the buffered data outputted from any one of the first and second buffers, and outputting the sliced signal; and
a driver suitable for driving the output terminal using the sliced signal.

3. The circuit of claim 1, wherein during an output operation of one of the first and second buffers, the other buffer floats from the output terminal.

4. The circuit of claim 3, wherein the first buffer comprises:
a first amplification unit suitable for receiving the input data and a reference voltage, amplifying a difference between the input data and the reference voltage, and outputting the amplified signal to the output terminal; and
a first switching unit suitable for being switched in response to a first enable signal, and controlling the first amplification unit to perform an output operation.

5. The circuit of claim 4, wherein the first amplification unit comprises a differential transistor pair and a current mirror.

6. The circuit of claim 4, wherein the first buffer further comprises:
an additional amplification unit suitable for receiving the input data and the reference voltage, amplifying a difference between the input data and the reference voltage, and outputting the amplified signal to the output terminal; and
an additional switching unit suitable for being switched in response to an inverted signal of the first enable signal, and controlling the additional amplification unit to perform an output operation.

7. The circuit of claim 4, wherein the second buffer comprises:
a second amplification unit suitable for receiving the input data and the reference voltage, amplifying a difference between the input data and the reference voltage, and outputting the amplified signal to the output terminal; and
a second switching unit suitable for being switched in response to a second enable signal, and controlling the second amplification unit to perform an output operation.

8. The circuit of claim 7, wherein the second amplification unit comprises a differential transistor pair and a current mirror.

9. The circuit of claim 7, wherein the second buffer further comprises:
an additional amplification unit suitable for receiving the input data and the reference voltage, amplifying a difference between the input data and the reference voltage, and outputting the amplified signal to the output terminal; and
an additional switching unit suitable for being switched in response to an inverted signal of the second enable signal, and controlling the additional amplification unit to perform an output operation.

10. A memory device comprising:
a memory cell array; and
a circuit suitable for providing data received from a data pad to the memory cell array,
wherein the circuit comprises:
a first buffer suitable for operating at a first supply voltage, buffering input data received through an input terminal, and outputting the buffered data to an output terminal; and
a second buffer suitable for operating at a second supply voltage, buffering the input data received through the input terminal, and outputting the buffered data to the output terminal,
wherein the first and second buffers share the output terminal, and alternately perform output operations under control of a control signal.

11. The memory device of claim 10, further comprising:
a slicer suitable for slicing the buffered data outputted from any one of the first and second buffers, and outputting the sliced signal; and
a driver suitable for driving the output terminal using the sliced signal.

12. The memory device of claim 10, wherein during an output operation of one of the first and second buffers, the other buffer floats from the output terminal.

13. The memory device of claim 12, wherein the first buffer comprises:
a first amplification unit suitable for receiving the input data and a reference voltage, amplifying a difference between the input data and the reference voltage, and outputting the amplified signal to the output terminal; and
a first switching unit suitable for being switched in response to a first enable signal, and controlling the first amplification unit to perform an output operation.

14. The memory device of claim 13, wherein the first amplification unit comprises a differential transistor pair and a current mirror.

15. The memory device of claim 13, wherein the first buffer further comprises:
an additional amplification unit suitable for receiving the input data and the reference voltage, amplifying a difference between the input data and the reference voltage, and outputting the amplified signal to the output terminal; and
an additional switching unit suitable for being switched in response to an inverted signal of the first enable signal, and controlling the additional amplification unit to perform an output operation.

16. The memory device of claim 13, wherein the second buffer comprises:
a second amplification unit suitable for receiving the input data and the reference voltage, amplifying a difference between the input data and the reference voltage, and outputting the amplified signal to the output terminal; and
a second switching unit suitable for being switched in response to a second enable signal, and controlling the second amplification unit to perform an output operation.

17. The memory device of claim 16, wherein the second amplification unit comprises a differential transistor pair and a current mirror.

18. The memory device of claim 16, wherein the second buffer further comprises:
an additional amplification unit suitable for receiving the input data and the reference voltage, amplifying a difference between the input data and the reference voltage, and outputting the amplified signal to the output terminal; and
an additional switching unit suitable for being switched in response to an inverted signal of the second enable signal, and controlling the additional amplification unit to perform an output operation.
